(19) United States
(12) Patent Application Publication
(10) Pub. No.: US 2026/0343827 A1
(43) Pub. Date: Oct. 29, 2026

(54) LIQUID COOLING OF COMPUTER EQUIPMENT

(71) Applicant: Schlumberger Technology Corporation, Sugar Land, TX (US)

(72) Inventor: Andrew Clarke, Cambridge (GB)

(21) Appl. No.: 19/311,013

(22) Filed: Aug. 27, 2025

(30) Foreign Application Priority Data
Apr. 28, 2025 (GB) 2506413.0

(51) Int. Cl. H05K 7/20; G06F 1/20

(52) U.S. Cl. CPC H05K 7/20763; G06F 1/20; H05K 7/20236; H05K 7/20272

(57) ABSTRACT

Servers in a data center are cooled by immersion in a non-conducting dielectric fluid which is circulated through a heat exchanger. Space around the immersed electronic components include a packing of non-conductive beads with beads touching the electronic components. The packing reduces the volume of dielectric fluid required. The coolant liquid contains suspended thermoresponsive microgel particles which transition from a swollen state to an unswollen state in proximity to the hotter electronic components, reducing viscosity and giving more flow of coolant over the hotter components than over others. The coolant may be in a state of elastic turbulence and may include particles which change phase from solid to liquid, enhancing heat capacity of the fluid.

### CROSS REFERENCE TO RELATED APPLICATIONS

This application claims priority to GB Patent Application No.: 2506413.0, which was filed on Apr. 28, 2025, and is incorporated herein by reference in its entirety.

### FIELD

This disclosure relates to cooling of electronic components and circuit boards carrying electronic components. It may be used for cooling in data centers.

### BACKGROUND

A data center typically contains numerous racks of circuit boards on which there are electronic components which produce heat as they operate. Consequently, it is conventional that a data center has a system for cooling these components during operation. Such systems may transfer the heat to a larger cooling system which may in turn transfer the heat to the environment outside the building.

There are a number of methods for cooling circuit boards or individual components of those boards. A system of forced air cooling has often been used. However, when the heat output is large, liquid cooling may be used. One system for liquid cooling uses a circulating liquid which is not electrically conducting, referred to as a “dielectric fluid”, and immerses heat emitting components and at least part of the circuit board to which the components are attached, in a tank of the dielectric fluid. This arrangement has been referred to as “total liquid cooling” or “immersion cooling”. The dielectric fluid which has been heated then transfers that heat to another cooling system in order that the heat can be taken out of the building. This may be done by using a heat exchanger to transfer the heat from the dielectric fluid to a water-based cooling system. A pump may be required to circulate the dielectric fluid between locations where it collects heat energy and a heat exchanger where the heat energy is discharged to some other system.

Immersion cooling may require a considerable quantity of dielectric fluid and this may require the racks and the building structure to be strongly constructed in order to carry the weight of liquid. Flow of dielectric fluid through the tank may be inefficient in that only part of the fluid flows close to the heat-emitting components and so a significant part of the dielectric fluid is pumped around a circuit while collecting very little of the heat energy coming from the components which need to be cooled.

### SUMMARY

This summary is provided to introduce concepts that will be further elaborated and described below in the detailed description. This summary is not intended to identify key or essential features of the claimed subject matter, nor is it intended to be used as an aid in limiting the scope of the claimed subject matter.

A first aspect of this disclosure is computing equipment comprising one or more circuit boards each having a plurality of electronic components attached thereto and a cooling system for the electronic components, comprising an electrically non-conductive coolant liquid and a container for the coolant liquid with the electronic components immersed in the liquid, and a pump configured to propel a flow of the coolant liquid over the electronic components, where the equipment further comprises a packing of electrically non-conductive beads adjacent to the immersed electronic components with at least some of the beads touching the electronic components whereby the packing defines a network of paths for flow through the packing and also in contact with the electronic components.

Thus, space around the immersed circuit boards and the attached electronic components which would otherwise be filled with dielectric fluid is partially occupied by the beads. These beads may touch the electronic components in places, while allowing flow of the coolant liquid over their surfaces. These beads may reduce the volume of dielectric fluid required in the container. If they have an average density which is less than the density of the circulating liquid they will reduce the weight of the container and its contents.

A second aspect of this disclosure is a method of cooling computing equipment comprising circuit boards each having a plurality of electronic components attached thereto, the method comprising placing a packing of electrically non-conductive beads adjacent to the electronic components with at least some of the beads touching the electronic components whereby the packing defines a network of paths for flow through the packing and also in contact with the electronic components, immersing the circuit boards and packing in an electrically non-conductive coolant liquid, and pumping a flow of the coolant liquid through the network of flow paths and over the electronic components while the computing equipment is in operation.

In some forms of this disclosure some of the electronic components emit more heat and become hotter than others when operating and the coolant liquid comprises suspended thermoresponsive microgel particles which transition from a swollen state to an unswollen state in proximity to the hotter electronic components, thereby selectively increasing the flow of coolant over the hotter components. This may make the collection of heat from the electronic components more efficient by directing more fluid to the hotter components.

### BRIEF DESCRIPTION OF THE DRAWINGS

FIG. 1 is a schematic cross section of a data center building.

FIG. 2 is a schematic cross section of a computing device on line Y-Y of FIG. 3.

FIG. 3 is a cross section on line X-X of FIG. 2.

FIG. 4 is a schematic sectional view of a coolant bath on line B-B of FIG. 1.

FIG. 5 is a schematic sectional view of the coolant bath on line C-C of FIG. 4.

FIG. 6 is a cross section of the coolant bath and associated heat exchanger, omitting packing contained within the computing device.

FIG. 7 is a cross section of the computing device shown in FIG. 6 on the line D-D of FIG. 6, with the packing shown.

FIG. 8 diagrammatically shows a microgel particle in swollen and unswollen states.

FIG. 9 is a graph of viscosity against volume fraction for increasing concentrations of particles of constant size.

FIG. 10 is a cross section of a computing device as in FIG. 6, with the sides of the bath also shown and the packing omitted, indicating regions with differing rates of flow.

FIG. 11 is a cross section of pillars of the heat exchanger shown in FIG. 6.

### DETAILED DESCRIPTION

This detailed description shows various embodiments of the present disclosure and possibilities which may be used. These are given as examples and do not limit this disclosure as defined by the claims. It should be appreciated that features or possibilities described in combination may, where it is practical to do so, be used separately. Also, features or possibilities described in any embodiment may be used in any other embodiment, in so far as it is possible to do so.

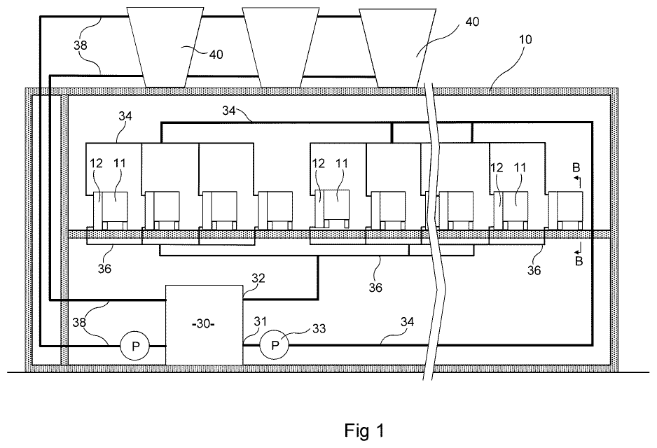

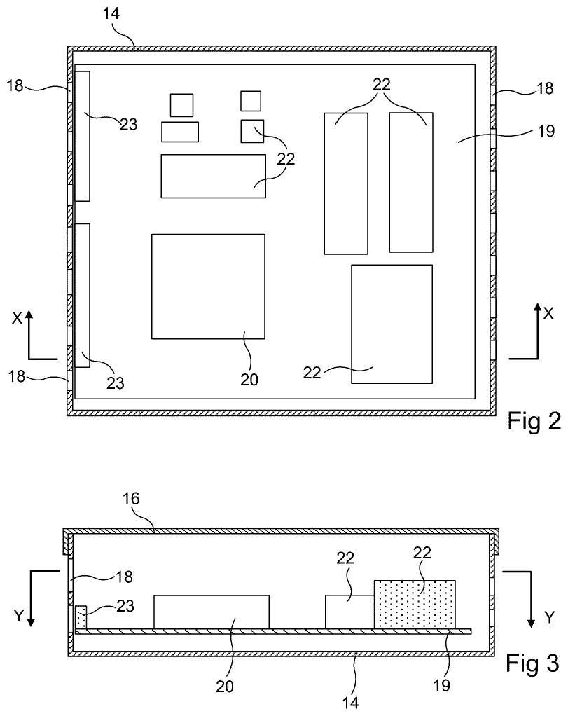

FIG. 1 is a schematic cross section of a building which is a data center 10. The building contains a number of units each of which comprises a bath 11 and a heat exchanger 12. The bath is constructed to contain a number of computing devices, such as servers. One such computing device is shown schematically by FIGS. 2 and 3. It has an outer case 14 which includes a removable cover 16. Inside the case 14 there is a printed circuit board 19 to which various electronic components are soldered. In this example, the components include a CPU 20 as well as other components 22. The case 14 has openings 18 at opposite ends to allow entry and exit of flowing coolant through and also to allow electrical connections to connector blocks 23.

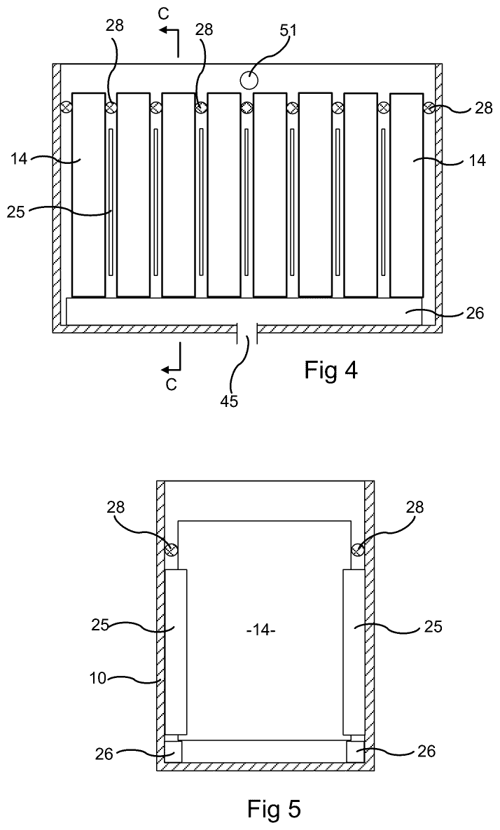

Positioning of computing devices in a bath 11 is shown in FIGS. 4 and 5. The computing devices with cases 14 are fitted into bath 11 from above. They fit between guides 25 and rest on supports 26 within the bath 11 so that there is space for flow of dielectric fluid below the computing devices in the bath.

Cooling of the computing devices and of the data center involves several systems. For primary cooling of the computing devices in each bath 11 the dielectric fluid is circulated through the computing devices and the adjacent heat exchanger 12. Each heat exchanger 12 is connected to a system in which an aqueous coolant liquid heated at the heat exchangers 12 is circulated by a pump 33. Heated coolant from heat exchangers 12 flows through a system of pipework 34 to the inlet 31 of a large heat exchanger 30 and then returns from the outlet 32 through another branching system of pipework to the heat exchangers 12. The branching systems of pipework 34, 36 may include pipes of various sizes and may also include components other than pipes. For example, the system 36 which carries flow from the outlet 32 of the heat exchanger 30 to the heat exchangers 12 may include flow controlling valves and/or auxiliary pumps to control the proportions of flow in each of a number of pipes extending from a branch point. The large heat exchanger 30 transfers the heat energy to water flowing in another flow circuit 38 which carries the heat to cooling towers 40 on the roof of the data center 10.

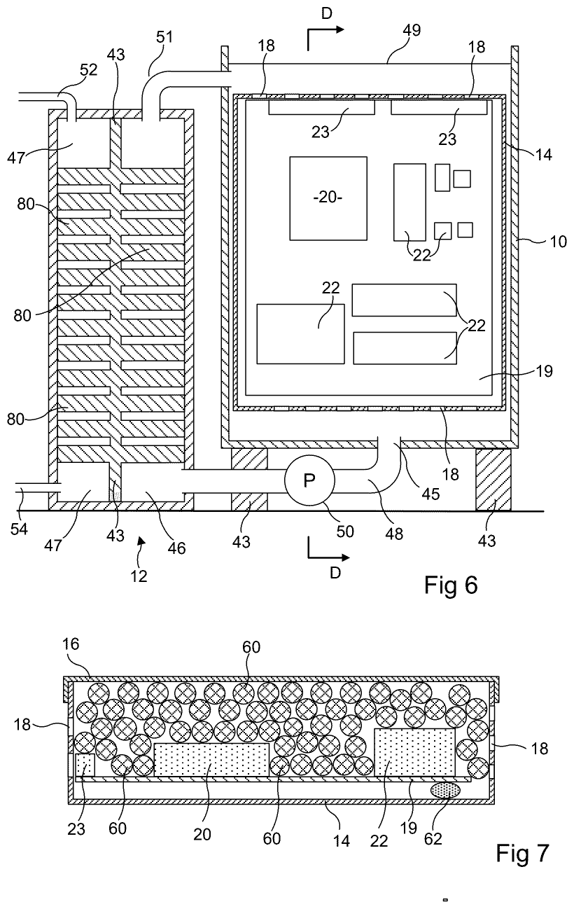

A bath 11 and heat exchanger 12 are shown in more detail in FIG. 6. The bath 11 is raised on supports. The heat exchanger 12 alongside the bath 11 has a divider 43 separating its two chambers 46, 47. The chamber 46 is connected to the bottom inlet 45 of the bath 11 by pipe 48 with a pump 50 to propel dielectric fluid from the chamber 46 into the bath 11 through bottom inlet 45. The fluid then flows upwardly into and through the cases 14 of the computing devices. It enters and leaves through the holes 18 in the cases 14. The seals 28 between the individual computing devices and between these devices and the bath 11 prevent dielectric fluid from flowing upwardly outside the cases 14. The surface of the dielectric fluid in the bath 11 is indicated at 49. Dielectric fluid flows back to the chamber 46 through pipe 51. The chamber 47 of the heat exchanger 12 has an inlet 52 connected to the pipework system 36 and an outlet 54 connected to the pipework system 34 for coolant circulated by the pump 33 to flow through this chamber 47 of the heat exchanger 12 to collect heat energy from the dielectric fluid flowing through the chamber 46. Within the bath 11, the dielectric fluid flows through each of the computing devices to cool the heat emitting component or components therein, which in this example is the CPU 20.

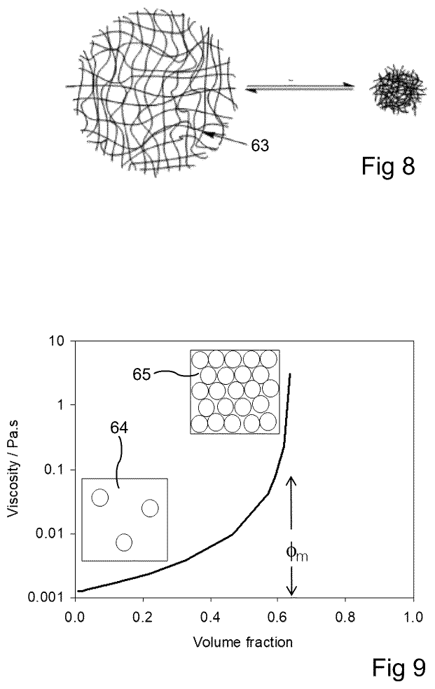

In accordance with this disclosure, the space above the circuit board 19 and attached electronic components is filled with a packing of beads 60. This may conveniently be completed when the items of computing equipment are assembled, before the cover 16 is fitted to the case 14 and so confines the beads. (These beads are shown in FIG. 8 but were omitted from FIG. 7 so that the electronic components 20, 22 can be seen). The presence of the beads 60 occupying space within the cases 14 of each item of computing equipment reduces the amount of dielectric fluid which is required to fill the bath 11. The beads may be spherical and may be hollow, i.e. with an air-filled but otherwise empty sealed interior, which will reduce their overall weight and so reduce the overall weight of the bath and its contents.

The electronic components on a circuit board may not all emit heat to the same extent. In particular CPUs and GPUs may emit considerably more heat than other components. In order to direct coolant flow to components which are emitting heat more than others, some embodiments of this disclosure use thermoresponsive microgels as a constituent of the dielectric fluid. Microgels have been defined as cross-linked polymer latex particles, which may be in the size range of 10-1000 nm, that form stable colloidal dispersions. Microgels may respond to a number of conditions surrounding them by changing from a swollen state to an unswollen state and vice-versa. FIG. 9 illustrates this reversible transition between an unswollen state (at the right) in which the polymer chains are packed close together and a swollen state with the polymer chains separated from one another while still held together by cross links which maintain the shape of the particle. One cross link is indicated at 63.

Thermoresponsive microgels respond to temperature, and typically change between their unswollen and swollen states over a small range of temperature. As an example, the well-studied material poly N-isopropylacrylamide (polyNIPAM) is hydrophobic at high temperature so that particles collapse in water to a size of about 50 nm. Viscosity is then low. When cool the polymer chains become hydrophilic so the material swells to a particle size of about 120 nm and the viscosity is high. The change takes place over a temperature range from 30 to 35 °C.

The viscosity of a dispersion of colloidal particles is dependent on the volume fraction occupied by the particles. The relation between viscosity and volume fraction is the Krieger-Docherty relation:

$$η = {\tilde{η}}_{0} ( 1 - \frac{ϕ}{{ϕ}_{m}} \text{?} \qquad ( 0.1 )$$

$$\text{?} \text{indicates text missing or illegible when filed}$$

with η the viscosity, η₀, the continuous phase viscosity (here of water), φ the volume fraction of dispersed particles and φ_{μ} the maximum packing of particles at which jamming occurs (0.64 for monodisperse spheres, ~0.8 for highly polydisperse) and [η] is intrinsic viscosity (2.5 for spheres).

Viscosity rises as the concentration of particles increases, until the concentration of the particles is such that they become packed closely together, referred to as jamming. This is illustrated by FIG. 9, in which a dilute dispersion and a close-packed jammed dispersion are shown as insets 64 and 65.

When microgel particles swell, their volume fraction of the overall composition increases, and so viscosity also increases, without change in concentration.

One well studied microgel material is poly N-isopropyl polyacrylamide (polyNIPAM). In microgels made from polyNIPAM the polymer is hydrophobic at high temperature so that particles collapse in water to a size of about 50 nm. Viscosity is then low. When cool the polymer chains become hydrophilic so the material swells to a particle size of about 120 nm and the viscosity is high.

With the above information the concentration of polyNIPAM to give jamming and hence very high viscosity at temperatures above the transition temperature can be calculated as follows

$$η ( {T}_{1} ) = {{η}_{0} ( 1 - \frac{k \cdot {d}_{1}^{3}}{{ϕ}_{m}} )}^{- 2.5 {ϕ}_{m}}$$

$$η ( {T}_{swollen} ) = {{η}_{0} ( 1 - \frac{k \cdot {d}_{swollen}^{3}}{{ϕ}_{m}} )}^{- 2.5 {ϕ}_{m}} = ∞$$

$$k \cdot {d}_{swollen}^{3} = {ϕ}_{m}$$

$$ϕ ( {T}_{1} ) = k \cdot {d}_{1}^{3} = {ϕ}_{m} ( \frac{{d}_{1}^{3}}{{d}_{swollen}^{3}} ) = 0.64 * {( \frac{50}{120} )}^{3} = 4.6 \%$$

Thus a very considerable change in viscosity can be provided by a small concentration of microgel particles.

Embodiments of the present disclosure may use a microgel at a concentration which gives an increased viscosity below the transition temperature but will not give complete jamming. When dielectric fluid containing such microgel particles is pumped over a circuit board on which some components are emitting enough heat energy to raise the temperature above the transition temperature, the lower viscosity will lead to a localized acceleration of flow, drawing in flow from other parts of the flow stream so that there is more coolant flow over the heat emitting components than other components which are emitting less heat. This enhances efficiency of the immersion cooling system.

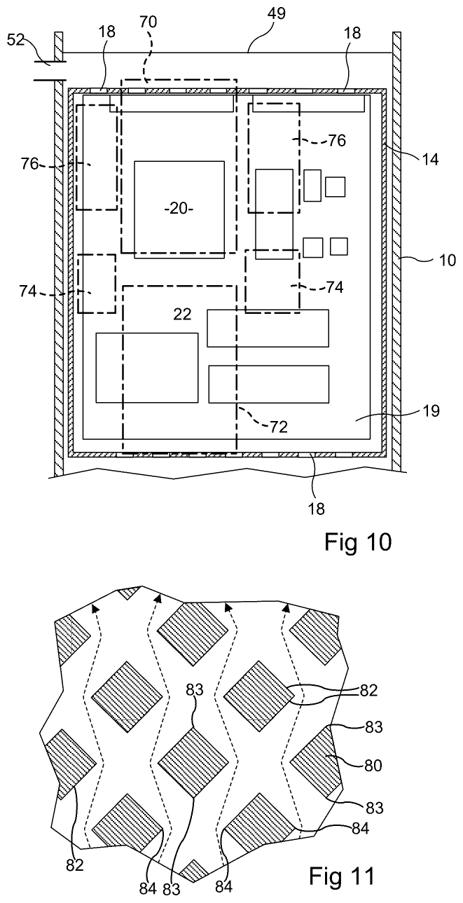

This is illustrated by FIG. 10 in which chain lines indicate various regions within the network of flow paths through the packing 60. Heat emitted from the CPU 20 raises the temperature of the flowing coolant in the area around it and above it, indicated by outline 70. This reduces the viscosity of the fluid within this region 70 and this heated fluid accelerates away from the flow through the upstream area 72. Flow from the region 74 is drawn into the faster flow of region 70, thereby reducing flow into the regions 76. In this way there is fuller use of the available coolant flow to collect heat from the CPU 20.

There is extensive scientific literature on the preparation and properties of microgels. Preparation of microgels which are soluble in non-aqueous solvents and description of properties in these solvents is given in Bonham et al, “Non-aqueous microgel particles: synthesis, properties and applications” Soft Matter, vol 10 page 9384 (2014), Bütün et al, “Novel multiresponse microgels, synthesis and characterized studies” Langmuir vol 27 page 12657 (2011) and Komarova et al “Behaviour of PNIPAM microgels in different solvents” Molecules vol 27 page 8549 (2022).

The liquid to be used as dielectric fluid in embodiments of the present disclosure where microgels particles are used may be a polar aprotic solvent, such as an ether or an ester or a halogenated compound such as a fluorocarbon.

Some embodiments of the present disclosure also use the phenomenon of elastic turbulence to enhance contact between the dielectric fluid and the electronic components to be cooled. Elastic turbulence was discovered during the latter part of the twentieth century. It occurs at a flow rate where a Newtonian liquid such as pure water would be in a state of laminar flow.

Some early observations of elastic turbulence used the older term “elastic instability”. However, that term is more general and includes other forms of instability in flow. Literature documents relating to elastic turbulence include a detailed discussion by Steinberg in Annual Review of Fluid Mechanics, vol 53, pages 27-58 (2021).

Elastic turbulence occurs in solutions containing a solute which has a flexible structure. One category of material able to undergo elastic deformation and enable a solution to display elastic turbulence is a polymer containing long flexible linear chains. The number of monomer units in the polymer may be at least 5000 and may be considerably more such as at least 25,000. The monomer units may be present in linear chains of at least 1000 monomer units which may each be connected one to the next by a single covalent bond, so that one monomer unit can rotate relative to adjoining monomer units. Individual linear chains may be longer and a polymer may contain a linear chain of at least 5000 or even at least 10,000 monomer units. A polymer chain may contain only one kind of monomer or the chain may be a copolymer of more than one monomer, for instance a block copolymer which is linear. A polymer may also include side chains attached to a long chain of monomer units which are connected together by single covalent bonds. If a chain contains units which are themselves an oligomer, as in a block copolymer for instance, the oligomeric units may rotate relative to one another more freely than monomer residues within an oligomeric unit. A polymer may include some chain branching, for instance at branch points where three or more linear chains, each of at least 1000 monomer units, are connected together. When using a long chain polymer to enable elastic turbulence to occur, it is desirable to include a biocide to protect the long chain linear polymer from biodegradation.

The flexibility of the polymer chains enables the polymer molecules to become entangled. The flexibility of polymer chains can be described by means of a mathematical model. The freely jointed chain model is commonly used and the flexibility of a particular polymer can be indicated by parameters of an equivalent freely jointed chain (itself a mathematical model). A description of this approach is provided by Chapter 2 of “Polymer Physics” by Rubinstein and Colby, 2003, Oxford University Press. An equivalent freely jointed chain has the same mean-square end-to-end distance and the same maximum end-to-end distance as the actual polymer but is considered to include so-called Kuhn monomers which are freely rotatable relative to each other. These model monomers have a length, termed the Kuhn length, and a molar mass.

Polymers to enable elastic turbulence may contain at least one flexible polymer chain with length and composition represented by at least 5000 Kuhn monomers having a Kuhn length not more than 100 Angstroms (10 nm) and possibly not more than 50 Angstroms. If a polymer is a single unbranched chain, its length and composition may correspond to at least 24,000 Kuhn monomers and possibly at least 50,000 Kuhn monomers.

The mean molecular weight of the polymer may be at least one Mega Dalton i.e. at least 106 Daltons, possibly at least 10 Mega Daltons or more. The concentration of such long chain/high molecular weight polymer included in a solution for enabling elastic turbulence to occur may be under 5% by weight, for instance in a range from 0.05% or 0.1% up to 1% or 2% by weight.

Elastic turbulence has been observed with several different long chain polymers in solution. One such polymer is polyacrylamide, which may be hydrolyzed or partially hydrolyzed. Experimental evidence for elastic turbulence in a solution of high molecular weight polyacrylamide was given by Groisman and Steinberg in “Elastic Turbulence in a polymer solution flow” Nature, Vol 45 p 53 (2000). Other instances of long chain polymers reported to give rise to elastic turbulence include polyisobutylene of molecular weight 4 to 6 Megadaltons dissolved in an organic solvent (Dris and Shaqfeh, J. Non-Newtonian Fluid Mech. Vol 80 pages 1 to 58 (298)), polystyrene of molecular weight 18 Megadaltons in an organic solvent (Magda and Larson, J. Non-Newtonian Fluid Mech. Vol 32 pages 1-2 (288)) and polyethylene oxide of molecular weight 4 MegaDaltons in an aqueous solution (Davoodi et al, J. Fluid Mech. Vol 857, pages 603-850 (2018)). Kuhn lengths for polystyrene and polyethylene oxide given by Rubinstein and Colby, page 53 are 18 Angstroms and 11 Angstroms. Kuhn length for polyacrylamides has been reported as 19 to 25 Angstroms (Fetters, Lohse and Colby, Chain Dimensions and Entanglement Spacings. In Physical Properties of Polymers Handbook; Mark, J. E., Ed.; Springer: New York, 2007; pages 447-454).

Long chain partially hydrolyzed polyacrylamide linear polymers with a molecular weight of more than 1 MegaDalton are available from SNF Floerger, whose headquarters are in Andrézieux, France.

Another category of material which is able to undergo elastic deformation and enable a solution to display elastic turbulence is a viscoelastic surfactant which forms worm-like micelles in solution. Such micelles have also been referred to as “rod-like”. Scientific literature concerning surfactants which form worm-like micelles, their properties and applications includes a review by Yang “Viscoelastic wormlike micelles and their applications” Current Opinion in Colloid & Interface Science vol 7 pages 276_311 (2002). Discussions of properties include Raghavan and Kaler “Highly Viscoelastic Wormlike Micellar Solutions Formed by Cationic Surfactants with Long Unsaturated Tails” Langmuir vol 22, pages 324-326 (2401) and Beaumont et al “Turbulent flows in highly elastic wormlike micelles” Soft Matter vol 9 page 735 (2013).

A number of viscoelastic surfactants which spontaneously form wormlike micelles in aqueous solution are set out in T. Saeki “Flow properties and heat transfer of drag reducing surfactant solutions” which is chapter 18 of “Developments in Heat Transfer” edited by D. M. A. D. S. Bernardes, published by InTechOpen, 2011. One possibility mentioned there is cetyl-trimethyl-ammonium chloride in a solution also containing sodium salicylate. Another possibility is stearyl-trimethyl-ammonium chloride which is effective in reducing drag at temperatures up to and above 100 °C. A suitable concentration of a viscoelastic surfactant to form wormlike micelles may be 10 μm/litre or less, possibly from 1 to 10 or 1 to 5 μm/litre. Such a compound may have a molecular weight not greater than 1000 Daltons.

When a solution contains a substance able to cause elastic turbulence, the phenomenon of elastic turbulence occurs if the solution is flowing at a sufficient flow velocity (which may be a low velocity and below velocities at which there is inertial turbulence) and the path of flow causes the streamlines of the flow to make a succession of changes of direction, thereby causing the direction of flow to curve. The changes in direction may be continuous curvature as in concentric or helical flow or may alternate between turning to the right and to the left.

In embodiments of the present disclosure the packing 60 of beads which creates the network of flow paths adjacent to the electronic components will compel the flow of dielectric fluid to make a succession of changes of direction, enabling elastic turbulence to occur.

Elastic turbulence can also be used to assist heat transfer in the heat exchangers 12. For this the divider 43 is made of a metal with good thermal conductivity, such as copper or aluminum, and at both sides it is integral with an array of pillars 80 of square cross section which extend to the side walls of the heat exchanger. The layout of this array is shown by the cross sectional view in FIG. 11. The pillars 80 have flat faces 82 meeting at corner edges 83 and 84. The flat faces 82 of each pillar are inclined to the overall direction of flow. Liquid flows through the gaps between confronting edges 84 of adjacent pillars 80, but is then compelled to turn by another pillar. Thus the array of pillars 80 causes the streamlines of the flow, which are indicated with broken lines in FIG. 6, to bend repeatedly.

In the chamber 46 the polymer or viscoelastic surfactant which enables elastic turbulence to occur within the packing 60 also enables elastic turbulence to occur as the fluid makes repeated changes of direction in chamber 46. The coolant which is circulated between the large heat exchanger 30 and the heat exchangers 12 also contains a polymer or viscoelastic surfactant enabling elastic turbulence to occur in the chamber 47. The elastic turbulence in the chambers 46 and 47 improves heat transfer from the dielectric fluid through the divider 43 and pillars 80 to the flowing coolant in chamber 47.

Some embodiments of this disclosure may use a dielectric fluid which is an emulsion or suspension in which the disperse phase is able to melt and to freeze at temperatures which are above the temperature of cooled dielectric fluid flowing into the bath 11 but below the temperature of dielectric fluid flowing out of the bath 11 and also below a maximum operating temperature for the electronic components which are being cooled by the circulating dielectric fluid. This will increase the heat carrying capacity of the dielectric fluid because melting of the disperse phase will require the latent heat of fusion of that phase in addition to heat to raise the temperature of the liquid.

Various embodiments of this disclosure have been set out above. These are intended to assist understanding of this disclosure, but not to limit it in any way. It should be appreciated that any features or possibilities described in combination may, where it is practical to do so, be used individually. Also, features or possibilities mentioned in the following claims or described in any embodiment may be used in any other embodiment, in so far as it is practical to do so and where two or more of the following claims are dependent on the same preceding claim, the reader should understand that the present disclosure includes any possible combination of any two or more or all of those dependent claims with each other and also with that preceding claim.

1. Computing equipment comprising one or more circuit boards each having a plurality of electronic components attached thereto and a cooling equipment for the electronic components, comprising:
an electrically non-conductive coolant liquid;
a container for the coolant liquid with the electronic components immersed in the liquid, and a pump configured to propel a flow of the coolant liquid over the electronic components;
the equipment further comprising a packing of electrically non-conductive beads adjacent to the immersed electronic components with at least some of the beads touching the electronic components whereby the packing defines a network of paths for flow through the packing and also in contact with the electronic components.

2. The equipment of claim 1, wherein the beads are hollow.

3. The equipment of claim 1, further comprising one or more cases having the circuit boards and the packing within the cases, wherein the cases have apertures dimensioned to allow flow of coolant liquid but retain the beads within the cases.

4. The equipment of claim 1, wherein the electronic components are such that some become hotter than others when operating and the coolant liquid comprises suspended thermoresponsive microgel particles which transition from a swollen state to an unswollen state in proximity to the hotter electronic components.

5. The equipment of claim 4, wherein the transition occurs at a temperature over 30 C but below 60 C.

6. The equipment of claim 2, wherein the coolant liquid comprises, in solution therein, a substance enabling the liquid to undergo elastic turbulence.

7. The equipment of claim 1, wherein the coolant liquid further comprises suspended particles of a substance which is insoluble in the coolant liquid and which has a melting temperature which is above 30 °C and below a working temperature limit of the electronic components.

8. The equipment of claim 7, wherein the melting temperature is in a range from 25 °C to 60 °C.

9. A method of cooling computing equipment comprising circuit boards each having a plurality of electronic components attached thereto, the components varying in their heat output during operation, the method comprising:
placing a packing of electrically non-conductive beads adjacent to the electronic components with at least some of the beads touching the electronic components whereby the packing defines a network of paths for flow through the packing and also in contact with the electronic components;
immersing the circuit boards and packing in an electrically non-conductive coolant liquid, and
pumping a flow of the coolant liquid through the network of flow paths and over the electronic components while the computing equipment is in operation.

10. The method of claim 9, wherein the beads are hollow.

11. The method of claim 9, wherein the circuit boards and electronic components on the circuit boards are enclosed in cases and the packing of beads is also in the cases, and wherein the cases have apertures dimensioned to allow flow of coolant liquid but retain the beads within the cases.

12. The method of claim 9, wherein the electronic components differ in their heat outputs during operation such that some become hotter than others when operating and the coolant liquid comprises suspended thermoresponsive microgel particles which transition from a swollen state to an unswollen state at a transition temperature which is above the temperature at which the liquid enters the network of flow paths and is such that hotter components on the circuit boards heat the flowing liquid to a temperature above the transition temperature whereby the liquid in contact with the hotter components becomes less viscous and the flow rate over these hotter components is greater than the flow rate over other components.

13. The method of claim 12, wherein the transition temperature is over 25 °C but below 60 °C.

14. The method of claim 9, wherein the coolant liquid comprises, in solution therein, a substance enabling the liquid to undergo elastic turbulence.

15. The method of claim 9, wherein the coolant liquid further comprises suspended particles of a substance which is insoluble in the coolant liquid and which has a melting temperature which is above the temperature at which the liquid enters the network of flow paths.

16. The method of claim 12, wherein the coolant liquid further comprises suspended particles of a substance which is insoluble in the coolant liquid and which has a melting temperature which is above the transition temperature of the microgel particles.
